(19) United States
(12) Patent Application Publication
(10) Pub. No.: US 2018/0090545 A1
(43) Pub. Date: Mar. 29, 2018

(54) OLED PIXEL ARRAY, METHOD FOR PREPARING OLED PIXEL ARRAY, OLED DISPLAY PANEL AND DISPLAY APPARATUS

(71) Applicants: BOE Technology Group Co., Ltd., Beijing (CN); Ordos Yuansheng Optoelectronics Co., Ltd., Inner Mongolia (CN)

(72) Inventor: Dongwei Li, Beijing (CN)

(21) Appl. No.: 15/520,475

(22) PCT Filed: Aug. 4, 2016
(86) PCT No.: PCT/CN2016/093224

§ 371 Date: Apr. 20, 2017

(30) Foreign Application Priority Data
Jan. 5, 2016 (CN) 201610005064.X

(51) Int. Cl. H01L 27/32; G09G 3/3208

(52) U.S. Cl. CPC H01L 27/3211; G09G 3/3208

(57) ABSTRACT

Disclosed is an OLED pixel array, comprising a plurality of pixel units arranged side by side in the direction of the line of the pixel array, wherein each of the pixel units is composed of one R sub-pixel, one G sub-pixel, and one B sub-pixel; in each of the pixel units, the B sub-pixel is an intermediate sub-pixel, and the R sub-pixel and the G sub-pixel are end sub-pixels; and adjacent end sub-pixels of two adjacent pixel units are the same sub-pixel. Further disclosed is a method for evaporating this pixel array with a fine metal mask, wherein adjacent sub-pixels having the same color in adjacent pixel units are evaporated in the same mask opening, as well as an OLED display panel and a display apparatus using the pixel array.

### CROSS-REFERENCE TO RELATED APPLICATIONS

This application is a Section 371 National Stage application of International Application No. PCT/CN2016/093224, filed on Aug. 4, 2016, which has not yet published, and claims priority to Chinese Patent Application No. 201610005064.X filed on Jan. 5, 2016, which are incorporated by reference herein in their entirety.

### TECHNICAL FIELD

The present disclosure relates to the field of organic electroluminescence, and particularly to an OLED pixel array, a method for preparing the OLED pixel array, an OLED display panel comprising the OLED pixel array, and a display apparatus.

### BACKGROUND

Panel display includes LCD display, OLED display, PDP display, electronic ink display, etc. By virtue of a number of advantages such as light weight and thin thickness, active light emission, high response speed, wide view angle, abundant colors as well as high brightness, low energy consumption, and good resistance to high and low temperatures, the organic light-emitting diode (OLED) display has been considered as a third-generation display technology subsequent to the liquid crystal display (LCD), and can be widely used in terminal products such as smartphones, tablet computers, televisions, etc.

A well-established technique for OLED is to prepare a color pixel pattern by arranging and evaporating organic light-emitting materials with a fine metal mask (FMM) in the order of standard red, green, and blue (hereafter, simply referred to as RGB sometimes) sub-pixels. In this process, color mixing may occur between adjacent sub-pixels having different colors, in particular between R and G sub-pixels, which severely influence the performance of display. Moreover, it is difficult to achieve a resolution more than 300 ppi, as limited by sizes of openings and connecting bridges of the fine metal mask.

Recently, the resolution of LCD display has been up to 400 ppi or more, and in the PCT/CN2016/093224 development trend, it will even exceed 500 ppi later, which makes a great challenge for the prior art of OLED.

In this industry, with respect to the problems encountered by the FMM technique, leading corporations, such as Samsung, Korea, etc., have actively investigated new techniques typified by LITI (laser induced thermal imaging) to intend to produce OLED display screens with higher resolution. However, these new techniques still have various disadvantages, and cannot be used for mass production or have low yield rate upon mass production. For example, it is required to add manufacture procedures and the additional manufacture processes result in relatively low production efficiency; it is required to add apparatuses and raw materials and it is even required to develop particular raw materials, resulting in increased investment and cost, etc. Even so, it is still difficult for these new techniques to produce display screens with ultrahigh resolution of 450 ppi or more.

Another approach for increasing resolution is to use a so-called Pentile pixel array. The Pentile pixel array comprises no pixel composed of three sub-pixels of red, green, and blue, but comprises a pixel composed of red and green sub-pixels and a pixel composed of blue and green sub-pixels, and it achieves full colors by one pixel plus the color of a sub-pixel, which this pixel lacks, in an adjacent pixel. Compared to a standard RGB pixel array, the Pentile pixel array can generate a higher pixel density with the same size of sub-pixels, since each pixel contains only two sub-pixels. However, this mode of array needs to borrow a sub-pixel in adjacent pixel, and upon display, problems of color difference, color edge, dark point, etc., often occur, which severely influence the display effect.

Therefore, there is still demand for the improvement of the method for preparing an OLED display screen with high resolution and high display quality by using a FMM evaporation process.

### SUMMARY

With respect to the above problems, this disclosure provides the following contents:

[1] An OLED pixel array, comprising a plurality of pixel units arranged side by side in the direction of the line of the pixel array, wherein each of the pixel units is composed of one R sub-pixel, one G sub-pixel, and one B sub-pixel; in each of the pixel units, the B sub-pixel is an intermediate sub-pixel, and the R sub-pixel and the G sub-pixel are end sub-pixels; and adjacent end sub-pixels of two adjacent pixel units are the same sub-pixel.

[2] The pixel array according to [1], wherein the distance between adjacent R end sub-pixels and/or the distance between adjacent G end sub-pixels is/are smaller than the distance between adjacent R-G sub-pixels in a standard RGB pixel array with the highest resolution prepared by a fine metal mask evaporation process.

[3] The pixel array according to [1] or [2], wherein the distance between adjacent R end sub-pixels and/or the distance between adjacent G end sub-pixels is/are as low as 10 μm.

[4] The pixel array according to any one of [1] to [3], wherein the distance between a B sub-pixel and an end sub-pixel adjacent thereto is greater than the distance between a B sub-pixel and a sub-pixel adjacent thereto in a standard RGB pixel array with the highest resolution prepared by a fine metal mask evaporation process.

[5] The pixel array according to any one of [1] to [4], wherein a B sub-pixel and an adjacent end sub-pixel have a distance such that color mixing does not occur between B sub-pixels evaporated by a mask evaporation process.

[6] The pixel array according to any one of [1] to [5], wherein R, G, B sub-pixels are aligned respectively among lines, or B sub-pixels are aligned but R and G sub-pixels are alternately arranged among lines.

[7] A method for preparing the pixel array of any one of [1] to [6], comprising evaporating R, G and B sub-pixels by a mask evaporation process, in which a R mask plate, a G mask plate, and a B mask plate are used to evaporate R, G and B sub-pixels on a back panel respectively, wherein

a red organic light-emitting material is evaporated at positions corresponding to two adjacent R end sub-pixels of adjacent pixel units in the pixel defining layer, through an opening on the R mask plate, to form the two adjacent R end sub-pixels;

a green organic light-emitting material is evaporated at positions corresponding to two adjacent G end sub-pixels of adjacent pixel units in the pixel defining layer, through an opening on the G mask plate, to form the two adjacent G end sub-pixels;

and a blue organic light-emitting material is evaporated at a position corresponding to a B sub-pixel in the pixel defining layer, through an opening on the B mask plate, to form the B sub-pixel.

[8] The process according to [7], wherein the mask plates are a fine metal mask plates.

[9] The process according to [8], wherein the widths of openings and connecting bridges of respective fine metal mask plates are set such that color mixing does not occur between sub-pixels in the pixel array obtained by evaporation.

[10] An OLED display panel, which uses the pixel array according to any one of [1] to [6].

[11] A display apparatus, comprising the display panel according to [10].

A first aspect of the present disclosure provides an OLED pixel array, comprising a plurality of pixel units, which are arranged side by side in the direction of the line of the pixel array, wherein each of the pixel units is composed of one R sub-pixel, one G sub-pixel, and one B sub-pixel, in each of the pixel units, the B sub-pixel is an intermediate sub-pixel, and the R sub-pixel and the G sub-pixel are end sub-pixels, and adjacent end sub-pixels of two adjacent pixel units are the same sub-pixel.

The pixel array of the present disclosure first prevents the occurrence of adjacent R and G sub-pixels. In the field of OLED display, the color mixing between red and green sub-pixels does the greatest harm, which severely reduces display effect. In this display array, adjacent red and green sub-pixels are absent, and thus the color mixing between red and green sub-pixels does not occur.

When the pixel array of the present disclosure is prepared by the method of the present disclosure using a mask evaporation process, two R sub-pixels or two G sub-pixels are evaporated in one mask (R or G mask) opening, so that smaller R and G sub-pixels may be obtained by using a mask having the same size of opening and thus smaller pixel units may be obtained to improve resolution.

Conversely, if the sizes of R and G sub-pixels are maintained unchanged, the pixel array of the present disclosure may be prepared by using R and G masks having a larger opening and a wider connecting bridge. The mechanical properties of these masks are superior to a mask having a small opening and a fine connecting bridge, so that the deformation of masks and thus accompanying disadvantages may be effectively prevented.

Preferably, the distance between adjacent R end sub-pixels is smaller than the distance between adjacent R-G sub-pixels in a standard RGB pixel array with the highest resolution prepared by a fine metal mask evaporation process. Preferably, the distance between adjacent G end sub-pixels is smaller than the distance between adjacent R-G sub-pixels in a standard RGB pixel array with the highest resolution prepared by a fine metal mask evaporation process. Preferably, the distance between adjacent R end sub-pixels and/or the distance between adjacent G end sub-pixels may be as low as 10 μm.

Since there is no problem of the color mixing between the same end sub-pixels of the present disclosure, the distance therebetween may be smaller than the distance between adjacent R-G sub-pixels in a standard RGB array respectively. Therefore, the margin between sub-pixels within the same length is reduced. Accordingly, the arrangement of sub-pixels is more compact, and thus the resolution can be improved.

Preferably, the distance between a B sub-pixel and an end sub-pixel adjacent thereto of the pixel array is greater than the distance between a B sub-pixel and a sub-pixel adjacent thereto in a standard RGB array having the same size of sub-pixel as that in the pixel array.

If the distance between a B sub-pixel and an adjacent sub-pixel increases, the possibility of the occurrence of the color mixing may be further reduced without changing the B mask.

Preferably, the distance between a B sub-pixel and an end sub-pixel adjacent thereto may ensure that color mixing does not occur between B sub-pixels evaporated by a mask evaporation process.

Preferably, among lines, R, G, B sub-pixels in different lines are aligned respectively, or B sub-pixels in different lines are aligned but R and G sub-pixels in different lines are alternately arranged. The two modes of constituting the entire RGB pixel array are advantageous in terms of preparation and display effect.

Another aspect of the present disclosure provides a method for preparing the pixel array of the present disclosure, which comprises evaporating R, G and B sub-pixels by a mask evaporation process, wherein, an R mask plate, a G mask plate, and a B mask plate are used in the mask evaporation process to evaporate R, G and B sub-pixels on a back panel respectively, wherein a pixel defining layer arranged according to the pixel array is formed on the back panel; a red organic light-emitting material is evaporated at positions corresponding to two adjacent R end sub-pixels of adjacent pixel units in the pixel defining layer, through an opening on the R mask plate, to form the two adjacent R end sub-pixels; a green organic light-emitting material is evaporated at positions corresponding to two adjacent G end sub-pixels of adjacent pixel units in the pixel defining layer, through an opening on the G mask plate, to form the two adjacent G end sub-pixels; and a blue organic light-emitting material is evaporated at a position corresponding to a B sub-pixel corresponding in the pixel defining layer, through an opening on the B mask plate, to form the B sub-pixel.

By the evaporation method described above, the same two sub-pixels may be evaporated in one opening of an end sub-pixel mask so as to improve resolution. At the meanwhile, the distance between the same two sub-pixels may be closer than the distance between different sub-pixels, and thus the resolution is further improved.

Preferably, the mask plates are fine metal mask plates.

More preferably, the widths of openings and connecting bridges of respective fine metal mask plates are set such that color mixing does not occur between sub-pixels in the pixel array obtained by evaporation.

Still another aspect of the present disclosure provides an OLED display panel using the pixel array of the first aspect of the present disclosure.

Still another aspect of the present disclosure provides a display apparatus using the OLED display panel described above.

### BRIEF DESCRIPTION OF DRAWINGS

FIG. 1 shows a schematic diagram of evaporating a standard RGB pixel array in the prior art.

FIG. 2 shows a schematic diagram of evaporating the pixel array of the present disclosure.

FIG. 3 is a schematic diagram of the arrangement in one line of the pixel array of the present disclosure.

FIGS. 4A-C show the circumstances when R, B and, G sub-pixels are evaporated respectively.

FIG. 5A schematically shows the distance between sub-pixels of a standard RGB pixel array.

FIG. 5B schematically shows the distances between sub-pixels of the pixel array of the present disclosure.

FIG. 5C schematically shows an embodiment of the distance between sub-pixels of a standard RGB pixel array.

FIG. 5D schematically shows an embodiment of the distances between sub-pixels of the pixel array of the present disclosure.

FIGS. 6A and 6B schematically show embodiments of the two-dimensional arrangement of the pixel array of the present disclosure respectively.

The same symbols in figures refer to the same or similar parts or elements.

### DESCRIPTION OF EMBODIMENTS

In a standard RGB pixel array in the prior art, an OLED pixel array is composed of pixel units, and each of the pixel units comprises three sub-pixels of red, green, and blue, (i.e., R sub-pixel, G sub-pixel, and B sub-pixel). In one line of the array, sub-pixels as well as pixel units are arranged side by side so as to form a pixel line wherein R, G, and B sub-pixels are orderly and circularly arranged.

A fine metal mask plate is a mask plate with high precision and has a fine opening thereon. In order to prepare a pixel array, two sub-pixels in R/G/B sub-pixels are shielded (for example, R sub-pixel and G sub-pixel are shielded) by using a shielding zone of a mask plate, and a body material of a light-emitting layer corresponding to a sub-pixel of another color (such as B sub-pixel) is deposited by an evaporation process. This is a mask evaporation process. R, G, and B sub-pixels are evaporated by using R, G, and B mask plates respectively to obtain a final pixel array.

The resolution (with a unit of ppi, pixels per square inch), which is one of important parameters of a display device, may be related to the two factors below. The first is the size of each sub-pixel. As sub-pixels become smaller, the number of sub-pixels in a unit area becomes larger, and thus the resolution becomes higher. However, the size of sub-pixel depends on the size of the opening of the mask plate used in evaporation. When the resolution is up to 300 ppi or more, the circular side-by-side pixel arrangement of the RGB sub-pixels described above requires very fine openings and connecting bridges (ribs connecting adjacent openings) of the fine metal mask plate. However, when the opening of mask plate becomes smaller, it will result in not only increased cost of the mask and significantly increased difficulty of production process (mainly etching and welding processes) and cleaning, but also reduced alignment accuracy when the mask is used, which causes a phenomenon of severe color mixing between prepared R, G, and B sub-pixels and reduced yield rate of production. Therefore, the size of the opening of the fine metal mask plate is one factor which limits the improvement of resolution. The second is the distance between respective sub-pixels. Assuming that the sub-pixel has a certain size, the pixel density is the largest when sub-pixels are closely adjacent to each other. However, this is only the ideal circumstance. Moreover, in practical production, a certain margin must be remained between sub-pixels to reduce the opportunity of the occurrence of color mixing. The larger the margin is, the less possibly the color mixing will occur. However, the less closely the sub-pixels are arranged, the lower the resolution is. Therefore, the width of the margin is another factor which limits the improvement of resolution.

The connecting bridge between the openings on the fine mask plate also influences the improvement of resolution. When the openings on the mask plate are made to be closer in order to improve resolution, the rib accordingly becomes narrower, and thus the mask plate is prone to be deformed by other factors, for example, it may subside due to gravity. The shade of the mask plate may also be influenced subsequently, leading to the problems including generation of color mixing.

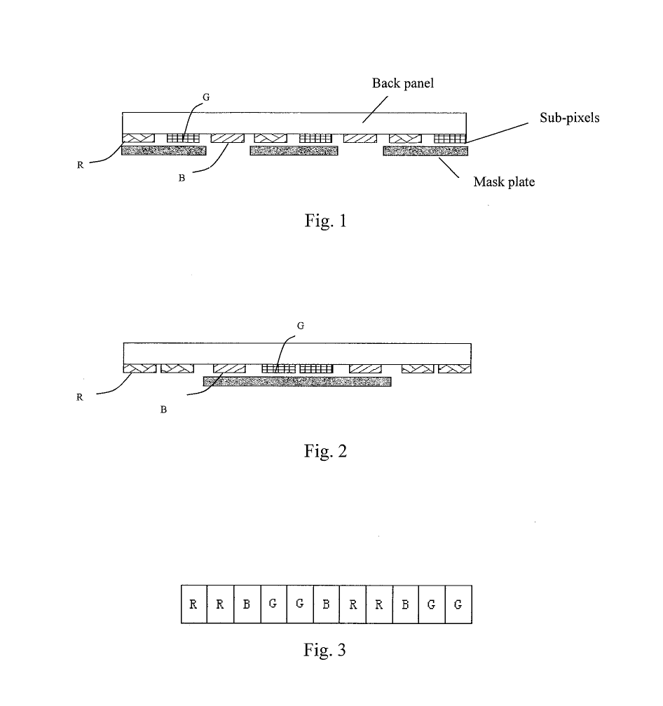

FIG. 1 shows a schematic diagram of evaporating a standard RGB pixel array in the prior art, wherein sub-pixels 2, including R, G, and B sub-pixels, are evaporated on back panel 1 by using mask plate (fine metal mask plate) 3. In one line of a standard RGB pixel array, R, G, and B sub-pixels are orderly and circularly arranged. FIG. 1 shows a schematic diagram upon the evaporation of B sub-pixels. Here, a connecting bridge of the fine metal mask plate 3 shields R sub-pixel and G sub-pixel, and a B sub-pixel is evaporated in an opening. In the figure, for the purpose of simplicity, R, G, and B sub-pixels are depicted to have substantially the same widths and substantially the same distances. Actually, as R, G, and B sub-pixels have different light-emitting materials, the widths thereof may be different. In general, compared to red and green organic light-emitting materials, the blue organic light-emitting material has relatively weak light emission, and therefore the B sub-pixel is widest among three sub-pixels. Moreover, the margin between respective sub-pixels is also related to color mixing of sub-pixels on both sides thereof. The color mixing between R sub-pixel and G sub-pixel does the greatest harm to the display effect. Therefore, it is typically required to have a relatively large margin between R sub-pixel and G sub-pixel.

In order to illustrate the advantages of the present disclosure, when compared to a standard RGB pixel array, the object selected for comparison is always “a standard RGB pixel array with the highest resolution prepared by a fine metal mask evaporation process”, unless particularly illustrated. This term means that the resolution, the color mixing level, the properties of fine metal mask, and the like of the standard RGB pixel array may be further improved with the improvement of the process level. However, the pixel array of the present disclosure still exhibits advantages over a standard RGB pixel array at exactly the same process level. In other words, the progresses of the pixel array of the present disclosure and the corresponding preparation method do not come from the improvements of general technical levels such as fine mask processing, organic light-emitting materials, evaporation process, etc., but inherently have advantages over a standard RGB pixel array.

FIG. 2 shows a schematic diagram of evaporating sub-pixel 2 on back panel 1 by using mask plate 3, to form the pixel array of the present disclosure. The arrangement of the pixel array of the present disclosure is shown in FIG. 3. Each of the pixel units is composed of one R sub-pixel, one G sub-pixel, and one B sub-pixel. In each of the pixel units, the intermediate sub-pixel is B sub-pixel, an end sub-pixel on one side is R sub-pixel and an end sub-pixel on other side is G sub-pixel. Adjacent end sub-pixels of two adjacent pixel units are the same, i.e. an R-R sub-pixel pair and a G-G sub-pixel pair are formed. In other words, in each line of the pixel array of the present disclosure, there is not standard -RGB-RGB-RGB-, but -RBG-GBR-RBG-GBR-. Importantly, although the same two end sub-pixels are adjacent, they emit light individually. That is, each of the pixel units is still a pixel unit which completely has RGB three colors, rather than the Pentile mode which needs to borrow the color of an adjacent pixel unit.

In the pixel array of the present disclosure, R sub-pixel is not adjacent to G sub-pixel. The color mixing between R sub-pixel and G sub-pixel does the greatest harm to the display effect. The pixel array of the present disclosure prevents the color mixing of R and G sub-pixels.

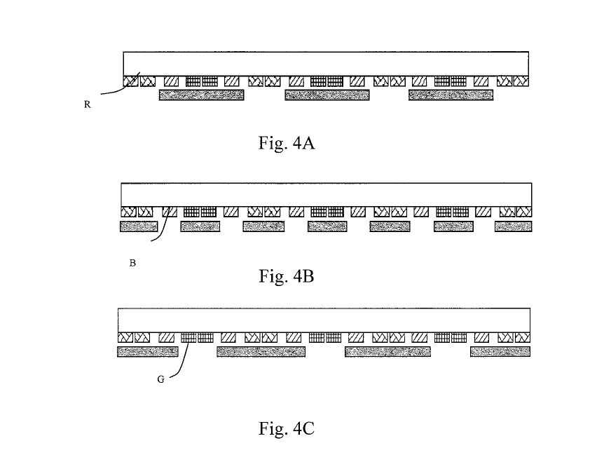

FIGS. 4A-C particularly show the circumstances when R, B and G sub-pixels are evaporated. The mask plates 3 in FIGS. 4A-C are R, B, and G mask plates respectively, and the grey part in the figure represents a connecting bridge between openings of mask plate 3. As seen from FIGS. 4A and 4C, two sub-pixels are evaporated in one opening of the mask plate 3, when R sub-pixel and G sub-pixel are evaporated.

Thus, by using the pixel array of the present disclosure, the sizes of openings on R mask plate and G mask plate may be approximately twice of the sizes of openings used for evaporating R and G sub-pixels having the same size in a standard RGB array. On the other hand, two sub-pixels may be prepared by using an opening having the same size with a previous one. To some extent, this solves the problem that improvement of resolution is limited by the size of opening. Moreover, the connecting bridge between openings covers 4 sub-pixels, instead of covering only 2 sub-pixels as for the connecting bridge of the mask used for evaporating a standard RGB array. For example, a connecting bridge between two openings of R mask shields two B sub-pixels and two G sub-pixels, while a connecting bridge between two openings of R mask in a standard RGB-RGB type pixel array shields only one B sub-pixel and one G sub-pixel. Therefore, when the sizes of sub-pixels are the same, the width of a connecting bridge may also be approximately twice of the width of a connecting bridge used for a standard RGB array, so that subsiding due to gravity or deformation due to other factors will not be prone to occur.

As shown in FIG. 4B, the number of sub-pixels between two B sub-pixels is still two. However, in the prior art, a B sub-pixel is always made to be the widest due to performance issue of blue organic light-emitting material. Therefore, the size of the opening of B mask is not a main factor which limits the current FMM process. As R and G sub-pixels having smaller widths are prepared, the opening of B mask still has the potential to be made smaller so as to improve resolution.

The pixel array of the present disclosure is also advantageous in that the distance between adjacent sub-pixels having the same color may be reasonably reduced and the distance between B sub-pixel and R sub-pixel or G sub-pixel may be reasonably increased.

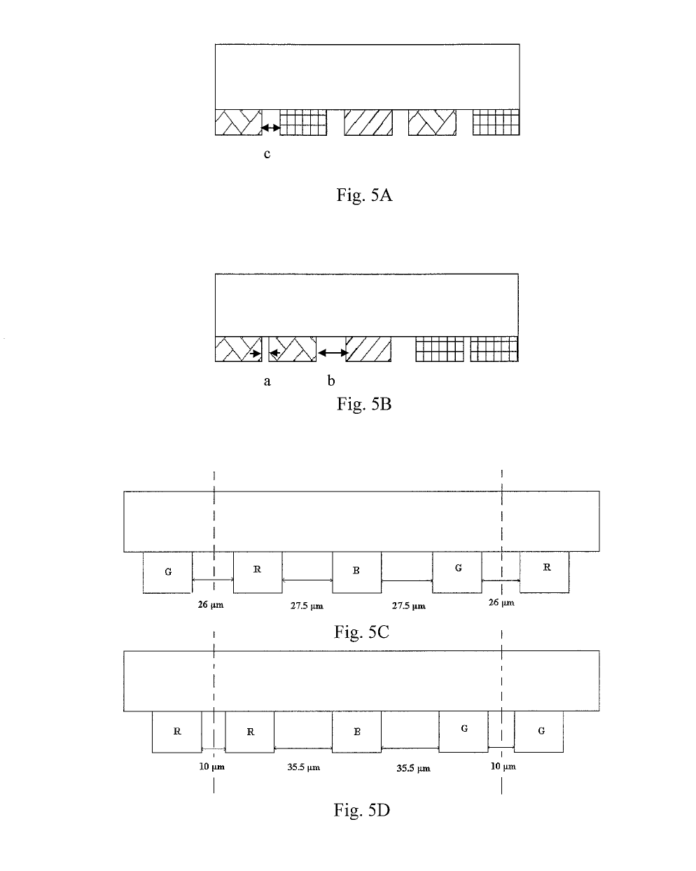

As mentioned above, margin is required between two adjacent sub-pixels having different colors to prevent the occurrence of color mixing or at least reduce the opportunity of the occurrence of color mixing to an acceptable range. As shown in FIG. 5A, in a standard RGB pixel array, the distance between sub-pixels having different colors may be “c”. Of course, the distances between three sets of adjacent sub-pixels (i.e., R-G, G-B, and B-R) may also be different. For the purpose of simplicity, FIG. 5A shows the case where all the distances are “c”. By contrast, FIG. 5B shows the case of the pixel array of the present disclosure. Since two adjacent end sub-pixels are sub-pixels having the same color, there is no problem of color mixing therebetween. Therefore, the distance therebetween, represented by “a” in FIG. 5B, may be smaller than “c”. That is, a<c. If the B-R distance and the B-G distance are still maintained constant compared to FIG. 5A, the distance between pixel units may be smaller than the original R-G distance. Therefore, more pixel units are arranged in the same length, so that the resolution of the pixel array is improved. The distance between the same adjacent end sub-pixels may be flexibly adjusted by the person skilled in the art according to practical needs. For example, it is possible to only reduce the distance between R sub-pixels, only reduce the distance between G sub-pixels, or reduce the two distances to different extents. It is easy for the person skilled in the art to do so. At the meanwhile, the distance between a B sub-pixel and an adjacent sub-pixel may also be properly increased, and may be “b” as shown in FIG. 5B, wherein b>c. “b” may have a flexible value, so that the overall resolution is still greater than or equal to the resolution of a standard RGB pixel array as a comparison reference. The value of b greater than the value of c is advantageous in that the opportunity of the occurrence of color mixing between B sub-pixel and adjacent sub-pixel is further reduced since the distance between sub-pixels increases. It is desirable that the distance between a B sub-pixel and an end sub-pixel adjacent thereto is such a distance that color mixing does not occur between B sub-pixels evaporated by a mask evaporation process.

More particularly, FIG. 5C shows a common case of margin between sub-pixels of a standard RGB pixel array in the state of the art. The distance between R and G sub-pixels is 26 μm. The distance between G and B sub-pixels and the distance between B and R sub-pixels are 27.5 μm. FIG. 5D shows an embodiment of the present disclosure, wherein the distance between R and R sub-pixels and the distance between G and G sub-pixels are 10 μm, while the distance between R and B sub-pixels and the distance between B and G sub-pixels are 35.5 μm. In the illustrated pixel unit comprising one R sub-pixel, one G sub-pixel, and one B sub-pixel which have the same size (the part between the dashed lines), the total lengths of margins are the same and are all 81 μm. However, the distances between B sub-pixel and R sub-pixel or G sub-pixel increase and the larger margin reduces the possibility of the occurrence of color mixing to a very low level.

Thus, compared to a standard RGB pixel array, it is possible to reduce the distance between R sub-pixels or G sub-pixels having the same color and/or increase the distance between B sub-pixel and adjacent sub-pixel having different color, by using the pixel array of the present disclosure, so as to improve resolution and/or prevent color mixing.

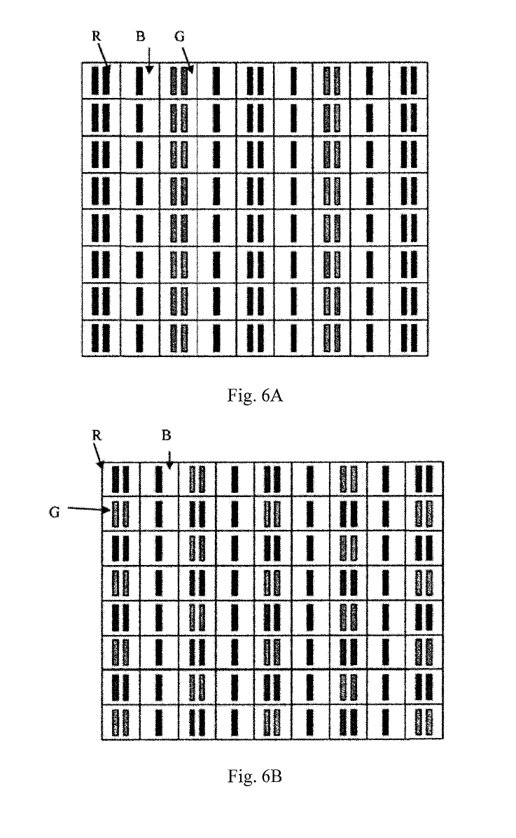

The whole pixel array may be obtained by extending the one line of pixels. Preferred embodiments are that among lines, R, G, B sub-pixels (in different lines) are aligned respectively (as shown in FIG. 6A), or B sub-pixels are aligned but R and G sub-pixels are alternately arranged (as shown in FIG. 6B).

In summary, compared to a side-by-side standard RGB pixel array, the pixel array of the present disclosure may have at least one of the following advantages, but is not limited thereto.

(1) R and G sub-pixels are not adjacent, so as to prevent the occurrence of color mixing of R and G sub-pixels.

(2) When R, G, and B sub-pixels having the same resolution and the same size are evaporated, R and G masks have relatively large openings and relatively wide connecting bridges, and difficulties in the process of preparation, use, cleaning, and the like of R and G masks may be reduced.

(3) At the same preparation level of masks, each opening of R and G masks may be used to prepare two smaller sub-pixels, and a higher resolution may be obtained in cooperation with a B sub-pixel having reduced size.

(4) At the same level of color mixing, the distance between adjacent end sub-pixels having the same color may be smaller than the distance between R-G sub-pixels in a standard side-by-side RGB pixel array, so that a higher resolution may be obtained.

(5) Using the same B mask, the distance between B sub-pixel and adjacent R or G sub-pixel is larger, and color mixing may be reduced.

(6) In the pixel array of the present disclosure, adjacent end sub-pixels belong to different pixel units and emit light individually, and thus each of the pixel units is a complete pixel unit having RGB three colors, and has good display effect.

In summary, the pixel arrangement of the present disclosure provides excellent solutions in terms of improving resolution, reducing color mixing, improving properties of fine metal masks, and allowing easier preparation and cleaning of fine metal masks.

In the present disclosure, the method for preparing the pixel array is still a mask evaporation process. However, due to the unique configuration of the pixel array, two R sub-pixels (or two G sub-pixels) can be evaporated in the same opening of an R mask (or a G mask) in the mask evaporation process of the present disclosure. Therefore, the method of the present disclosure may prevent the color mixing of R and G sub-pixels. Moreover, at the same production level of masks, an OLED pixel array with higher resolution may be prepared by the method of the present disclosure. Conversely, at the same level of resolution, the method of the present disclosure has relatively low requirements for the production level of masks.

Preferably, a fine metal mask commonly-used in the art is still used in the method of the present disclosure.

At the same production level of fine metal masks, color mixing is not prone to occur when the pixel array of the present disclosure is evaporated and resolution may be improved. In the case of preparing a pixel array having the same resolution, color mixing is not prone to occur and harsh requirements for fine metal masks are reduced. Since there is no color mixing between the same end sub-pixels, the problem of color mixing may be thoroughly prevented without reducing resolution, as long as the distances between B sub-pixel and R sub-pixel or G sub-pixel is properly increased.

In the method of the present disclosure, two sub-pixels are evaporated through the same opening on an R or G mask. For example, it can be accomplished by directly evaporating and depositing an organic material onto two adjacent sub-pixels. Two separate sub-pixels are naturally formed by depositing an organic light-emitting material onto two sub-pixels through the same opening. The distance between the two sub-pixels is determined by the distance in pixel defining layer (PDL) previously formed on a back panel. In the evaporation step described above, even if interference occurs in the process of the evaporation of the same two adjacent end sub-pixels, it will not result in the problem of color mixing, because the two sub-pixels have the same color. At this time, each of the sub-pixels still emits purely red or green light.

The number of R sub-pixel and/or G sub-pixel on two ends of a display panel may be still two. That is, the pixel arrangement thereof is, for example, R-RBG-GBR- . . . -RBG-GBR-R. At this point, the R (or G) sub-pixel at the utmost edge of the panel is a dummy zone, which does not emit light. Thus, a large mask opening may be still used when the sub-pixels at this edge are evaporated, and therefore it will not cause the problem that a small mask opening is required again for the sub-pixel at the edge of the panel.

In the method of the present disclosure, the mask plate may be adjusted according to practical situations and needs, to achieve intended effects of preparation. The adjustment includes but is not limited to the change of distance between sub-pixels, and the adjustment of the size of mask opening and the width of connecting bridge. By adjustment, one or more of the effects of improving resolution, increasing margin, reducing color mixing, preventing deformation of masks, etc., can be achieved

The detailed description above is merely for the purpose of illustration, not for limiting the invention. A person skilled in the art would have the capacity of obtaining various advantageous effects by using the pixel array and/or the method for preparing the pixel array of the present invention, based on the disclosures of the specification. Various modifications, which do not depart from the spirit of the invention, all fall in the scope of this invention.

1. An OLED pixel array, comprising a plurality of pixel units arranged side by side in the direction of the line of the pixel array, wherein each of the pixel units is composed of one R sub-pixel, one G sub-pixel, and one B sub-pixel; in each of the pixel units, the B sub-pixel is an intermediate sub-pixel, and the R sub-pixel and the G sub-pixel are end sub-pixels; and adjacent end sub-pixels of two adjacent pixel units are the same sub-pixel.

2. The pixel array according to claim 1, wherein the distance between adjacent R end sub-pixels and/or the distance between adjacent G end sub-pixels is/are smaller than the distance between adjacent R-G sub-pixels in a standard RGB pixel array with the highest resolution prepared by a fine metal mask evaporation process.

3. The pixel array according to claim 1, wherein the distance between adjacent R end sub-pixels and/or the distance between adjacent G end sub-pixels is/are as low as 10 μm.

4. The pixel array according to claim 1, wherein the distance between a B sub-pixel and an end sub-pixel adjacent thereto is greater than the distance between a B sub-pixel and a sub-pixel adjacent thereto in a standard RGB pixel array with the highest resolution prepared by a fine metal mask evaporation process.

5. The pixel array according to claim 1, wherein a B sub-pixel and an adjacent end sub-pixel have a distance such that color mixing does not occur between B sub-pixels evaporated by a mask evaporation process.

6. The pixel array according to claim 1, wherein R, G, B sub-pixels are aligned respectively among lines, or B sub-pixels are aligned but R and G sub-pixels are alternately arranged among lines.

7. A method for preparing the pixel array according to claim 1, comprising evaporating R, G and B sub-pixels by a mask evaporation process, in which a R mask plate, a G mask plate, and a B mask plate are used to evaporate R, G and B sub-pixels on a back panel respectively, wherein
a pixel defining layer arranged according to the pixel array is formed on the back panel,
a red organic light-emitting material is evaporated at positions corresponding to two adjacent R end sub-pixels of adjacent pixel units in the pixel defining layer, through an opening on the R mask plate, to form the two adjacent R end sub-pixels;
a green organic light-emitting material is evaporated at positions corresponding to two adjacent G end sub-pixels of adjacent pixel units in the pixel defining layer, through an opening on the G mask plate, to form the two adjacent G end sub-pixels;
and a blue organic light-emitting material is evaporated at a position corresponding to a B sub-pixel in the pixel defining layer, through an opening on the B mask plate, to form the B sub-pixel.

8. The method according to claim 7, wherein the mask plates are fine metal mask plates.

9. The method according to claim 8, wherein the widths of openings and connecting bridges of respective fine metal mask plates are set such that color mixing does not occur between sub-pixels in the pixel array obtained by evaporation.

10. An OLED display panel, which uses the pixel array according to claim 1.

11. A display apparatus, comprising the OLED display panel according to claim 10.

12. The pixel array according to claim 2, wherein the distance between a B sub-pixel and an end sub-pixel adjacent thereto is greater than the distance between a B sub-pixel and a sub-pixel adjacent thereto in a standard RGB pixel array with the highest resolution prepared by a fine metal mask evaporation process.

13. The pixel array according to claim 3, wherein the distance between a B sub-pixel and an end sub-pixel adjacent thereto is greater than the distance between a B sub-pixel and a sub-pixel adjacent thereto in a standard RGB pixel array with the highest resolution prepared by a fine metal mask evaporation process.

14. The pixel array according to claim 2, wherein R, G, B sub-pixels are aligned respectively among lines, or B sub-pixels are aligned but R and G sub-pixels are alternately arranged among lines.

15. The pixel array according to claim 3, wherein R, G, B sub-pixels are aligned respectively among lines, or B sub-pixels are aligned but R and G sub-pixels are alternately arranged among lines.

16. The pixel array according to claim 4, wherein R, G, B sub-pixels are aligned respectively among lines, or B sub-pixels are aligned but R and G sub-pixels are alternately arranged among lines.

17. The pixel array according to claim 5, wherein R, G, B sub-pixels are aligned respectively among lines, or B sub-pixels are aligned but R and G sub-pixels are alternately arranged among lines.
